(19) United States
(12) Patent Application Publication
(10) Pub. No.: US 2025/0294949 A1
(43) Pub. Date: Sep. 18, 2025

(54) ELECTRONIC DEVICE

(71) Applicant: INNOLUX CORPORATION, Miao-Li County (TW)

(72) Inventors: Yu-Tang CHUANG, Miao-Li County (TW); Tzu-Yuan LIN, Miao-Li County (TW); Che-Ming CHANG, Miao-Li County (TW); Ren-Fu GUO, Miao-Li County (TW)

(21) Appl. No.: 19/053,846

(22) Filed: Feb. 14, 2025

(30) Foreign Application Priority Data
Mar. 12, 2024 (CN) 202410279199.X

(51) Int. Cl. H10H 29/85; G02F 1/1333; H10K 59/80

(52) U.S. Cl. CPC H10H 29/8582; G02F 1/133382; H10K 59/8794

(57) ABSTRACT

An electronic device includes a casing, a heat source and a heat-dissipation unit. The casing has an accommodation space and a first surface. The heat source is arranged in the accommodation space. The heat-dissipation unit is disposed on the first surface. A part of the casing is located between the heat source and the heat-dissipation unit. The heat-dissipation unit has multiple tubular spaces with open ends. These tubular spaces respectively extend in a first direction parallel to the first surface and are arranged side by side on the first surface. The heat-dissipation unit has a height in a second direction perpendicular to the first surface, and at least one of the tubular spaces has a width in a third direction parallel to the first surface and perpendicular to the first direction. The ratio of the height to the width is between 1.4 and 5.2.

### CROSS REFERENCE TO RELATED APPLICATIONS

This Non-provisional application claims priority under 35 U.S.C. § 119 (a) on Patent Application No(s). 202410279199.X filed in People's Republic of China on Mar. 12, 2024, the entire contents of which are hereby incorporated by reference.

### BACKGROUND

### Technology Field

The present disclosure relates to an electronic device and, in particular, to an electronic device with a heat-dissipation function.

### Description of Related Art

In the field of display technology, light-emitting diodes (LEDs), such as organic light-emitting diodes (OLED), micro light-emitting diodes (Micro LED or uLED), etc., are one of the most promising technologies. The advantages of the LED display device include low power consumption, high contrast, wide color gamut, high brightness, small size, thinness and lightness, energy saving, etc.

Taking LED display devices as an example, they are often used in the outdoor multimedia displays. However, when the heat energy generated by internal heat-generating components plus the heat radiation of the external light exceeds the withstand temperature of the internal components of the display device, it may cause damage to the display device. The conventional LED display device usually utilizes an external circulation heat dissipation method to solve this problem. For example, a fan can be used with ventilation holes formed on the casing of the display device to introduce cold air from outside of casing into the inside of casing and to dissipate the inside hot air out of the casing. This design can dissipate the heat of the electronic components in the LED display device in the circulation heat dissipation method to maintain the normal operation of the LED display device. However, because the LED display device is usually installed in the outdoor environment for a long time, the dusts, water vapor and even small insects in the environment may enter the casing of the LED display device through the ventilation holes, which may cause damage to the electronic components inside the LED display device.

Therefore, it is desired to provide an electronic device that can prevent dusts, water vapor and foreign objects in the environment from entering the casing thereof as well as providing appropriate heat dissipation effect at the same time.

### SUMMARY

This disclosure provides an electronic device that can prevent dusts, water vapor and foreign objects in the environment from entering the casing thereof as well as providing appropriate heat dissipation effect at the same time.

An electronic device of this disclosure includes a casing, a heat source and a heat-dissipation unit. The casing has an accommodation space and a first surface. The heat source is arranged in the accommodation space. The heat-dissipation unit is disposed on the first surface of the casing, and a part of the casing is located between the heat source and the heat-dissipation unit. The heat-dissipation unit has a plurality of tubular spaces with open ends, and the tubular spaces respectively extend in a first direction parallel to the first surface and are arranged side by side on the first surface. The heat-dissipation unit has a height in a second direction perpendicular to the first surface. At least one of the tubular spaces has a width in a third direction, which is parallel to the first surface and perpendicular to the first direction. The ratio of the height to the width is between 1.4 and 5.2.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram showing an electronic device according to an embodiment of this disclosure;

FIG. 2 is a perspective sectional view of the electronic device of FIG. 1;

FIG. 3 is a sectional view of the heat-dissipation unit according to the embodiment of this disclosure;

FIG. 4 is a sectional view of one tubular space of the heat-dissipation unit according to the embodiment of this disclosure; and

FIG. 5 is a schematic diagram showing an electronic device according to another embodiment of this disclosure.

### DETAILED DESCRIPTION OF THE DISCLOSURE

The present disclosure will be apparent from the following detailed description, which proceeds with reference to the accompanying drawings, wherein the same references relate to the same elements. It should be understood that the following description provides different embodiments for implementing different aspects of some embodiments of the present disclosure. The specific components and arrangements described below are used to briefly and clearly describe some embodiments of the present disclosure. These embodiments are for illustration and are not intended to limit the scope of the present disclosure. In addition, reference numbers or labels may be repeatedly used in different embodiments. These repetitions are only for the purpose of simply and clearly describing some embodiments of the present disclosure, and do not represent any correlation between the different embodiments and/or structures discussed. Furthermore, when it is mentioned that a certain element is on or above another element, the certain element may directly contact another element, or one or more other elements may be provided between the two elements, so that the certain element may not directly contact another element.

Relative terms, such as “lower” and “higher”, or “bottom” and “top”, may be used in following embodiments to describe the relative relationship of one component to another component in the drawings. It will be understood that if the device shown in the drawings is turned upside down, components described as being at the “lower” side would then be at the “higher” side.

The terms “about”, “approximate” and “approximately” usually mean the variation within 20%, preferably within 10%, and more preferably within 5%, 3%, 2%, 1% or 0.5% of a given value or range. The given quantities here are approximate quantities, that is, in the absence of specific description of “about”, “approximate”, or “approximately”, the meaning of “about”, “approximate”, and “approximately” can still be implied.

It will be understood that, although the terms “first”, “second”, “third” and the likes may be used herein to describe various elements, components, regions, layers, and/or portions, these elements, components, regions, layers, and/or portions should not be limited by these terms, and these terms are used to distinguish between different elements, components, regions, layers, and/or portions. Thus, a first element, component, region, layer, and/or portion discussed below could be termed a second element, component, region, layer, and/or portion without departing from the teachings of some embodiments of the present disclosure.

Unless otherwise defined, all terms (including technical and scientific terms) used herein have the same meaning as commonly understood by one of ordinary skill in the related art. It is understood that these terms, such as those defined in commonly used dictionaries, should be interpreted to have a meaning consistent with the relevant technology and the background or content of the present disclosure, and should not be interpreted in an idealized or overly formal way, unless otherwise defined in the embodiments of this disclosure.

Some embodiments of the present disclosure can be understood together with the drawings, and the drawings of the embodiments of the present disclosure are also regarded as part of the description of the embodiments of the present disclosure. It should be understood that the drawings of the embodiments of the present disclosure are not drawn to the actual scale of devices and components. The shapes and thicknesses of embodiments may be exaggerated in the drawings to clearly illustrate features of embodiments of the present disclosure. In addition, the structures and devices in the drawings are illustrated in a schematic manner in order to clearly demonstrate the features of the embodiments of the present disclosure.

In some embodiments of the present disclosure, relative terms such as “lower”, “upper”, “parallel”, “vertical”, “below”, “above”, “top”, “bottom”, etc., shall be understood as the orientations shown in this paragraph and related drawings. These relative terms are for convenience of explanation and does not mean that the device described needs to be manufactured or operated in a specific orientation. Terms related to joining and connecting, such as “connect”, “joint”, etc., unless otherwise defined, can mean that two structures are in direct contact, or they can also mean that the two structures are not in direct contact with one or more additional structures located therebetween. The terms related to joining and connecting two structures can also include the situation that both structures are movable, or both structures are fixed.

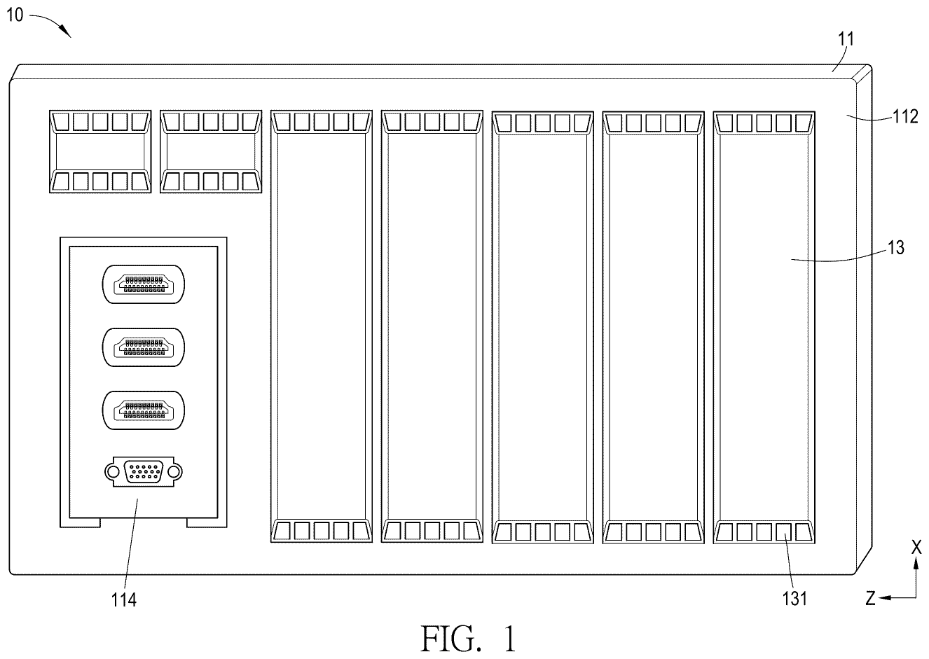

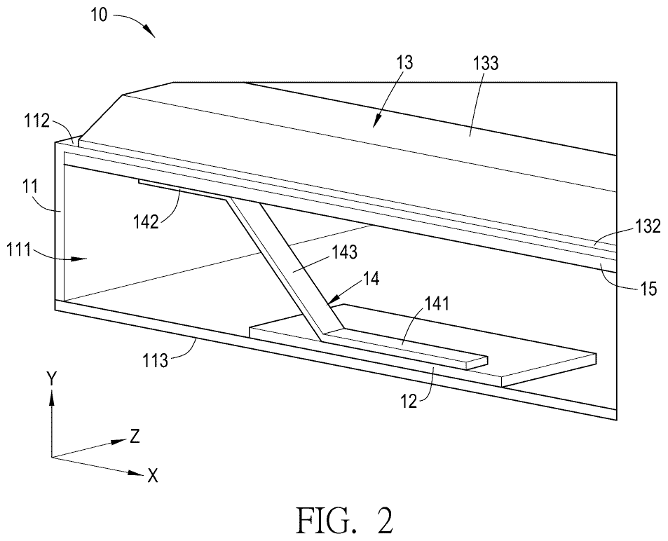

FIG. 1 is a schematic diagram showing an electronic device 10 according to an embodiment of this disclosure, and FIG. 2 is a perspective sectional view of the electronic device of FIG. 1. Referring to FIGS. 1 and 2, the electronic device 10 of this embodiment can be, for example but not limited to, an LED display device. To be noted, this disclosure is not limited thereto. In other embodiments, the electronic device 10 can be any of other types of electronic devices, especially the electronic devices suitable for outdoor applications. The electronic device 10 can be, for example but not limited to, a micro LED display device, a mini LED display device, an OLED display device, a quantum dot LED display device, an LCD device, or the like.

As shown in FIGS. 1 and 2, the electronic device 10 of this embodiment includes a casing 11, a heat source 12, and a heat-dissipation unit 13. Referring to FIG. 2, the casing 11 has an accommodation space 111 and a first surface 112, the heat source 12 is arranged in the accommodation space 111, and the heat-dissipation unit 13 is disposed on the first surface 112 of the casing 11. A part of the casing 11 is located between the heat source 12 and the heat-dissipation unit 13. In this embodiment, the first surface 112 of the casing 11 can be, for example but not limited to the outer surface of the back plate of the casing 11. Therefore, the heat-dissipation unit 13 is arranged at the outer side of the back plate of the casing 11. To be noted, the above illustration is for an example, and is not to limit the scope of this disclosure.

In order to make the electronic device 10 of this embodiment suitable for the outdoor environment, on one hand, the accommodation space 111 needs to be formed into a closed space (i.e., the casing of the electronic device has no ventilation holes for external air to flow in) to prevent the environmental dust, water vapor or even small insects from entering the casing 11 of the electronic device 10 through the ventilation holes, which may cause damage to the internal electronic components of the electronic device 10. On the other hand, the heat-dissipation unit 13 is configured to provide sufficient heat dissipation efficiency to prevent the electronic device 10 from being overheated and causing damage to the internal electronic components thereof. In one embodiment, the electronic device 10 can meet the requirement of waterproof IP rating of IP66 or above. For example, the electronic device 10 of the present disclosure has a fully enclosed design of outdoor machine, and has a brightness of 3000 nits, a waterproof IP rating of IPX6 or above, and a dustproof IP rating of IP6X or above. Therefore, when the outdoor temperature is as high as 50° C., the internal temperature of the electronic device 10 can still be maintained within the operating temperature specification and normally operated. To be noted, the operating conditions of the electronic device 10 of the present disclosure is not limited thereto. In this embodiment, the casing 11 itself can provide a completely sealed accommodation space 111. In another embodiment, the casing 11 can be assembled with a display panel (not shown) to form the accommodation space 111 into a closed space. To be noted, the above illustration is for an example, and is not to limit the scope of this disclosure.

In this embodiment, if the electronic device 10 is an LED display device, the heat source 12 can be, for example but not limited to, the LED display unit (including multiple LEDs), the driving circuit and the control circuit of the electronic device 10. In addition, in this embodiment, the casing 11 may further include a second surface 113 that is opposite to the first surface 112, and the heat source 12 is located between the first surface 112 and the second surface 113. If the electronic device 10 is an LED display device, the second surface 113 can be, for example but not limited to, a display surface of the electronic device 10, and the user can face the display surface and view the displayed images. To be noted, the above illustration is for an example, and is not to limit the scope of this disclosure.

To be understood, in order to receive signals from the outside of the electronic device 10, the first surface 112 of the casing 11 may include a connection port arrangement area 114. One or more signal receiving ports may be arranged in the connection port arrangement area 114 according to product specifications.

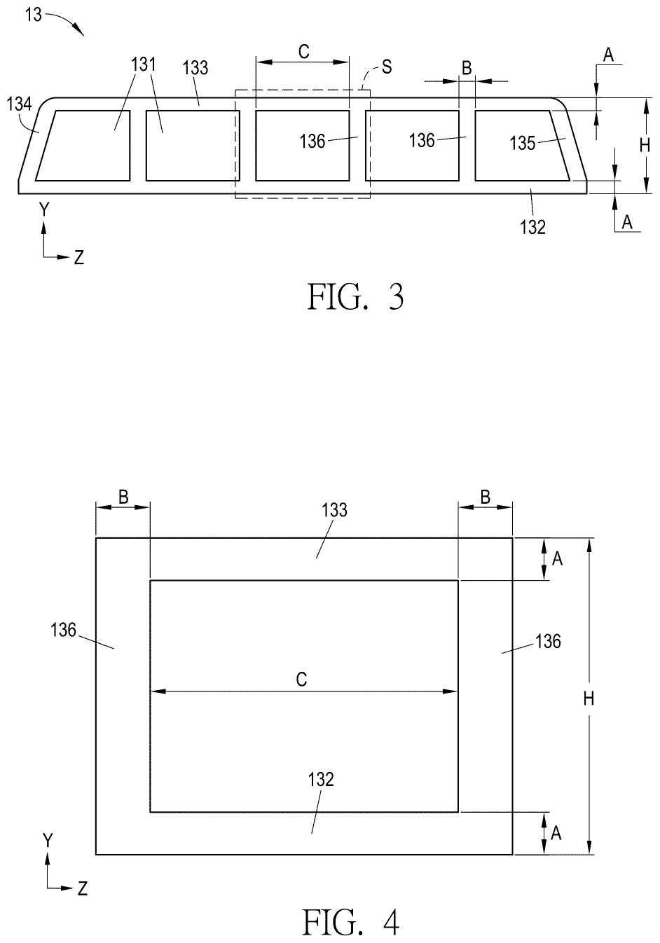

The following example will be described with reference to FIGS. 1 to 3. FIG. 3 is a sectional view of the heat-dissipation unit 13 according to the embodiment of this disclosure. To be noted, FIG. 3 shows the cross-sectional view of the heat-dissipation unit 13 along a cross section perpendicular to a first direction X.

As shown in FIGS. 1 to 3, the heat-dissipation unit 13 has a plurality of tubular spaces 131 with open ends. The tubular spaces 131 respectively extend in a first direction X parallel to the first surface 112 and are arranged side by side on the first surface 112. In addition, the heat-dissipation unit 13 is defined with a height H in a second direction Y perpendicular to the first surface 112. At least one of the tubular spaces 131 is defined with a width C in a third direction Z, which is parallel to the first surface 112 (i.e., perpendicular to the second direction Y) and perpendicular to the first direction X. The ratio of the height H to the width C is between 1.4 and 5.2 (1.4≤H/C≤5.2). In this embodiment, the first direction X is parallel to the direction of gravity. Therefore, when the air inside the tubular spaces 131 absorbs heat energy and becomes hot air, the hot air will move upward and leave the tubular spaces 131 through the upper openings of the tubular spaces 131. At the same time, the cold air in the external environment will enter the interior of the tubular spaces 131 from the lower openings of the tubular spaces 131. In this way, the natural convection can be generated, so that the heat-dissipation unit 13 can achieve the heat-dissipation effect without configuring the additional fan.

To be noted, in this embodiment, multiple heat-dissipation units 13 can be configured on the first surface 112 of the casing 11. For example, as shown in FIG. 1, multiple heat-dissipation units 13 can be arranged side by side on a heat-dissipation plate (not shown) to form a heat-dissipation assembly, and then the heat-dissipation plate 13 can be disposed on the first surface 112 of the casing 11. In another case as shown in FIG. 2, each heat-dissipation unit 13 can be directly attached to the first surface 112 of the casing 11. In this embodiment, each heat-dissipation unit 13 may include, for example but not limited to, five tubular spaces 131, and the heat-dissipation units 13 can be separated from each other or connected to each other. In addition, with considering the position of the connection port arrangement area 114 of the first surface 112 and/or the appearance structure of the casing 11, the heat-dissipation units 13 of different lengths can be optionally used to cover partial, most or all of the first surface 112, thereby improving the heat-dissipation efficiency thereof. To be noted, the above illustration is for an example, and is not to limit the scope of this disclosure.

Particularly, the heat-dissipation unit 13 of this embodiment is formed with a plurality of tubular spaces 131, and the dimensions of the heat-dissipation unit 13 and the tubular spaces 131 are designed to have the ratio of the height H to the width C, which is between 1.4 and 5.2. This design can obtain a balance between heat-dissipation effect, material cost and overall weight so as to provide the electronic device 10 with good product competitiveness.

In this embodiment, as shown in FIG. 3, the heat-dissipation unit 13 includes a first sidewall 132, a second sidewall 133, a third sidewall 134, a fourth sidewall 135 and at least two partition walls 136. The first sidewall 132 is disposed next to the first surface 112. The second sidewall 133 is disposed opposite to the first sidewall 132 and is located away from the first surface 112, and the third sidewall 134 is disposed opposite to the fourth sidewall 135. Two side edges of the third sidewall 134 are respectively connected to one side edge of the first sidewall 132 and one side edge of the second sidewall 133, and two side edges of the fourth sidewall 135 are respectively connected to another side edge of the first sidewall 132 and another side edge of the second sidewall 133. Therefore, the heat-dissipation unit 13 can a heat-dissipation space with two open ends. In addition, the partition wall 136 is disposed between the first sidewall 132 and the second sidewall 133, and two side edges of the partition wall 136 are connected to the first sidewall 132 and the second sidewall 133 respectively. Therefore, a plurality of tubular spaces 131 can be formed in the heat-dissipation space. In this embodiment, as shown in FIG. 3, there are totally four partition walls 136 provided in the heat-dissipation space, so the heat-dissipation space can be divided into five tubular spaces 131. In other words, a part of the first sidewall 132, a part of the second sidewall 133, and at least two of the partition walls 136 constitute one of the tubular spaces 131. To be noted, the above illustration is for an example, and is not to limit the scope of this disclosure.

As shown in FIG. 3, in this embodiment, each of the first sidewall 132 and the second sidewall 133 is defined with a thickness A. In one embodiment, each of the first sidewall 132, the second sidewall 133, the third sidewall 134 and the fourth sidewall 135 is defined with a thickness A. In addition, each of the partition walls 136 is defined with a thickness B. To be noted, the above illustration is for an example, and is not to limit the scope of this disclosure.

FIG. 4 is a sectional view of one tubular space 131 of the heat-dissipation unit 13 according to the embodiment of this disclosure. In particular, FIG. 4 shows a sectional view of one tubular space 131 of the heat-dissipation unit 13 referring to the dotted-line area S as shown in FIG. 3. Referring to FIGS. 3 and 4, in the cross section of the tubular space 131 of this embodiment, a part of the first sidewall 132, a part of the second sidewall 133 and the two partition walls 136 that constitute the tubular space 131 together define an inner cross-sectional area and an outer cross-sectional area. The ratio of the inner cross-sectional area to the outer cross-sectional area is between 0.1 and 0.9. Specifically, as shown in FIG. 4, the dotted-line area S (as shown in FIG. 3) includes two partition walls 136 and a part of the first sidewall 132 and a part of the second sidewall 133, wherein each of the first sidewall 132 and the second sidewall 133 has a thickness A, and each of the partition walls 136 have a thickness B. Therefore, the above-mentioned inner cross-sectional area can be calculated by the following formula (1):

$$inner cross - sectional area = C * ( H - 2 A ) \qquad formula ( 1 )$$

In addition, the above-mentioned outer cross-sectional area can be calculated by the following formula (2):

$$outer cross - sectional area = ( C + 2 B ) * H \qquad formula ( 2 )$$

Therefore, when the condition defined in this embodiment is that the ratio of the inner cross-sectional area to the outer cross-sectional area is between 0.1 and 0.9, then the following formula (3) can be obtained:

$$0.1 \leq [ C * ( H - 2 A ) ] / [ ( C + 2 B ) * H ] \leq 0.9 \qquad formula ( 3 )$$

As mentioned above, in order to make the electronic device 10 of this embodiment have better product competitiveness, the heat-dissipation unit 13 can be designed and manufactured according to the constraints of the above formulas (1) to (3), so that the electronic device 10 can achieve a balance between the heat-dissipation effect, material cost and overall weight.

Moreover, in this embodiment, the thickness A of the first sidewall 132, the second sidewall 133, the third sidewall 134 and the fourth sidewall 135 can be designed within an appropriate range to achieve a balance between heat-dissipation effect, material cost and overall weight. For example, the thickness A of at least one of the first sidewall 132, the second sidewall 133, the third sidewall 134 and the fourth sidewall 135 may be, for example but not limited to, between 1 mm and 7 mm (i.e., 1 mm≤thickness A≤7 mm). In addition, the thickness B of the partition wall 136 can also be designed within an appropriate range to achieve a balance between heat-dissipation effect, material cost and overall weight. For example, the thickness B of the partition wall 136 may be, for example but not limited to, between 1 mm and 4 mm (i.e., 1 mm≤thickness B≤4 mm). In addition, the height H of the heat-dissipation unit 13 can also be designed within an appropriate range to achieve a balance between heat dissipation effect, material cost and overall weight. For example, the height H of the heat-dissipation unit 13 may be, for example but not limited to, between 7 mm and 26 mm (i.e., 7 mm≤height H≤26 mm). To be noted, the above illustration is for an example, and is not to limit the scope of this disclosure.

In this case, the first sidewall 132, the second sidewall 133, the third sidewall 134 and the fourth sidewall 135 of the heat-dissipation unit 13 can together form, for example but not limited to, a trapezoid. Specifically, as shown in FIGS. 1 and 3, the size of the second sidewall 133 is slightly smaller than the size of the first sidewall 132. For example, in the third direction Z, the length of the second sidewall 133 is smaller than the length of the first sidewall 132. Therefore, in a cross section perpendicular to the first direction X, the first sidewall 132, the second sidewall 133, the third sidewall 134 and the fourth sidewall 135 forming the heat-dissipation spaces together form a trapezoid. To be noted, the above illustration is for an example, and is not to limit the scope of this disclosure.

Referring to FIG. 2, in this embodiment, the heat source 12 is located next to the second surface 113 of the casing 11, and a gap is defined between the heat source 12 and the first surface 112 of the casing 11. The dimension of the gap is defined by the size of the casing 11. In addition, the electronic device 10 of this embodiment may further include a plurality of heat pipes 14, which are disposed in the accommodation space 111 and located between the heat source 12 and the first surface 112 of the casing 11. At least a portion of the heat pipes 14 has a bent or curved shape. More specifically, at least one of the heat pipes 14 includes a first part and a second part, and the first part is relatively non-parallel to the second part or is bent relative to the second part. For example, in this embodiment, each of the heat pipes 14 has a first end 141, a second end 142, and a middle portion 143 between the two ends 141 and 142. The middle portion 143 is relatively non-parallel to (or is bent relative to) the first end 141, and the first end 141 of at least one heat pipe 14 is in direct or indirect contact with the heat source 12 to absorb the heat energy generated by the heat source 12. The second end 142 is in direct or indirect contact with (the first surface 112 of) the casing 11 so as to transfer heat energy to the casing 11. For example, in one embodiment, the first end 141 of at least one heat pipe 14 is in direct contact with the heat source 12. In another embodiment, the first end 141 of the at least one heat pipe 14 can be, for example but not limited to, in indirect contact with the heat source 12 through a thermal conductive paste. In this case, the thermal conductive paste can be, for example but not limited to, a silicon-containing thermal conductive paste, which can be a polysiloxane-based material with high thermal conductive fillers (e.g. metal-containing materials). Therefore, the thermal conductive paste can have excellent electrical insulation and thermal conductivity, so that it can be used for a long time in a temperature range from −60° C. to 250° C. without being prone to drying, hardening or melting. In other embodiments, the thermal conductive paste can be silicon-free thermal conductive paste, and this disclosure is not limited thereto.

In one embodiment, the second end 142 of at least one heat pipe 14 is in direct contact with (the first surface 112 of) the casing 11, so that the heat energy can be directly transferred from the heat pipe 14 to the casing 11. In another embodiment, the second end 142 of at least one heat pipe 14 may be in indirect contact with the casing 11 through, for example but not limited to, a thermal conductive member 15, so that the heat energy can be transferred from the heat pipe 14 to the casing 11 through the thermal conductive member 15. In this case, the thermal conductive member 15 may be, for example but not limited to, a thermal conductive component made of aluminum ingots, and the thermal conductive member 15 may have a flat plate or have several fins. The thermal conductive member 15 can be disposed in the accommodation space 111 and is arranged on an inner wall of the casing 11 opposite to the first surface 112, and the second end 142 of the heat pipe 14 is connected to the heat conductive member 15. In addition, the thermal conductive paste can be disposed between the second end 142 and the casing 11, and/or between the second end 142 and the heat conductive member 15, and/or between the casing 11 and the heat conductive member 15, and this disclosure is not limited thereto. Based on this configuration, the heat energy generated by the heat source 12 can be conducted to the casing 11 through the thermal conductive paste, the heat pipe 14 and the heat conductive member 15 in sequence, and then be dissipated into the environment through the heat-dissipation unit 13. To be noted, the above illustration is for an example, and is not to limit the scope of this disclosure.

In this embodiment, the electronic device 10 is, for example, a landscape type display device. In other embodiments, the electronic device 10 can be, for example, a portrait type display device.

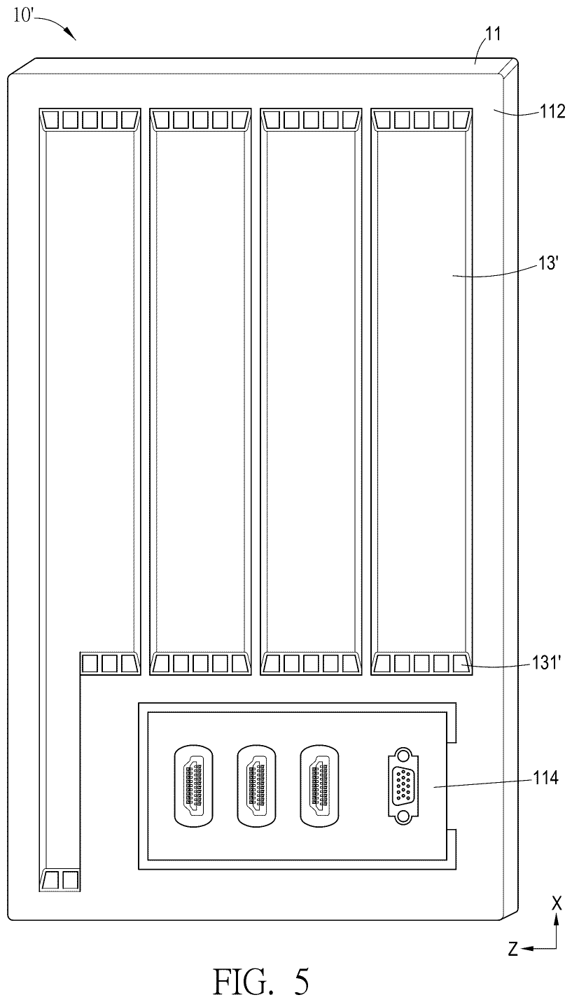

Referring to FIG. 5, the electronic device 10′ according to another embodiment of this disclosure may be, for example but not limited to, a portrait type display device, which includes a casing 11, a heat source (not shown), and a heat-dissipation unit 13′. In this embodiment, the heat-dissipation unit 13′ has a plurality of tubular spaces 131′ with open ends, and these tubular spaces 131′ respectively extend in a first direction X (direction of gravity) parallel to the first surface 112 and are arranged side by side on the first surface 112. Therefore, when the air inside the tubular spaces 131′ absorbs heat energy to form hot air, the hot air will move upward and leave the tubular spaces 131′ from the upper openings of the tubular spaces 131′. At the same time, the cold air in the external environment will enter the interior of the tubular spaces 131′ from the lower openings of the tubular spaces 131′. In this way, the natural convection can be generated, so that the heat-dissipation unit 13′ can achieve the heat-dissipation effect without configuring the additional fan. To be noted, the structure and configuration of each component in the electronic device 10′ of this embodiment can refer to those of the electronic device 10 of the previous embodiment, so the detailed descriptions thereof will be omitted.

To be noted, the features in any embodiment may be applied to other embodiments as long as they do not violate the spirit of the disclosure or conflict with each other.

In summary, the electronic device of this disclosure includes a casing, a heat source and a heat-dissipation unit. The casing has an accommodation space and a first surface. The heat source is arranged in the accommodation space. The heat-dissipation unit is disposed on the first surface of the casing, and a part of the casing is located between the heat source and the heat-dissipation unit. The heat-dissipation unit has a plurality of tubular spaces with open ends, and the tubular spaces respectively extend in a first direction parallel to the first surface and are arranged side by side on the first surface. The heat-dissipation unit has a height in a second direction perpendicular to the first surface. At least one of the tubular spaces has a width in a third direction, which is parallel to the first surface and perpendicular to the first direction. The ratio of the height to the width is between 1.4 and 5.2. Compared with the conventional art, the accommodation space inside the electronic device of the present disclosure can form a sealed space, so that the electronic device can be suitable for outdoor environments, which can prevent dust, water vapor, and/or even small insects in the environment from entering the electronic device through the ventilation holes and thus cause damages to the internal electronic components of the electronic device. On the other hand, the design of the heat-dissipation unit can provide appropriate heat-dissipation effect, so that the electronic device can still maintain its internal temperature within the operating temperature specification and allow the normal operation in the high temperature outdoor environments.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device, comprising:
a casing having an accommodation space and a first surface;
a heat source arranged in the accommodation space; and
a heat-dissipation unit disposed on the first surface of the casing, wherein a part of the casing is located between the heat source and the heat-dissipation unit;
wherein, the heat-dissipation unit has a plurality of tubular spaces with open ends, the tubular spaces respectively extend in a first direction parallel to the first surface and are arranged side by side on the first surface, the heat-dissipation unit has a height in a second direction perpendicular to the first surface, at least one of the tubular spaces has a width in a third direction, which is parallel to the first surface and perpendicular to the first direction, and a ratio of the height to the width is between 1.4 and 5.2.

2. The electronic device of claim 1, wherein the heat-dissipation unit comprises a first sidewall, a second sidewall, a third sidewall, a fourth sidewall, and at least two partition walls, the first sidewall is disposed next to the first surface, the second sidewall is disposed opposite to the first sidewall and located away from the first surface, the third sidewall is disposed opposite to the fourth sidewall, the third sidewall respectively connects to one side edge of the first sidewall and one side edge of the second sidewall, the fourth sidewall respectively connects to another side edge of the first sidewall and another side edge of the second sidewall, and the at least two partition walls are disposed between the first sidewall and the second sidewall.

3. The electronic device of claim 2, wherein a part of the first sidewall, a part of the second sidewall, and the at least two partition walls construct at least one of the tubular spaces; and
wherein, the part of the first sidewall, the part of the second sidewall, and the at least two partition walls together define, in a cross-sectional surface perpendicular to the first direction, an inner cross-sectional area and an outer cross-sectional area, and a ratio of the inner cross-sectional area to the outer cross-sectional area is between 0.1 and 0.9.

4. The electronic device of claim 2, wherein at least one of the first sidewall, the second sidewall, the third sidewall and the fourth sidewall has a thickness between 1 mm and 7 mm.

5. The electronic device of claim 2, wherein the first sidewall, the second sidewall, the third sidewall and the fourth sidewall of the heat-dissipation unit together form, in a cross-sectional surface perpendicular to the first direction, a trapezoid.

6. The electronic device of claim 2, wherein a thickness of the partition wall is between 1 mm and 4 mm.

7. The electronic device of claim 1, wherein the height is between 7 mm and 26 mm.

8. The electronic device of claim 1, wherein a gap is defined between the heat source and the first surface.

9. The electronic device of claim 1, further comprising a plurality of heat pipes arranged in the accommodation space and located between the heat source and the first surface, wherein at least one of the heat pipes has a first end contacting the heat source.

10. The electronic device of claim 9, wherein the first end is in indirect contact with the heat source through a thermal conductive paste.

11. The electronic device of claim 9, wherein the at least one of the heat pipes further has a second end contacting the casing.

12. The electronic device of claim 11, wherein the second end is in indirect contact with the casing through a thermal conductive member.

13. The electronic device of claim 9, wherein the at least one of the heat pipes has a bent shape or a curved shape.

14. The electronic device of claim 9, wherein the at least one of the heat pipes comprises a first part and a second part, and the first part is relatively non-parallel to the second part.

15. The electronic device of claim 1, wherein the electronic device comprises a micro LED display device, a mini LED display device, an OLED display device, a quantum dot LED display device, or an LCD device.

16. The electronic device of claim 1, wherein the accommodation space is formed into a closed space.

17. The electronic device of claim 1, wherein the casing further has a second surface disposed opposite to the first surface, and the heat source is located between the first surface and the second surface.

18. The electronic device of claim 1, wherein the first surface of the casing includes a connection port arrangement area, and one or more signal receiving ports are arranged in the connection port arrangement area.

19. The electronic device of claim 1, wherein the first direction is parallel to a direction of gravity.

20. The electronic device of claim 1, wherein the heat-dissipation unit is arranged on a heat-dissipation plate to form a heat-dissipation assembly, and the heat-dissipation plate is disposed on the first surface of the casing.
